(19) United States
(12) Patent Application Publication
(10) Pub. No.: US 2026/0239894 A1
(43) Pub. Date: Aug. 13, 2026

(54) RRAM Memory Cell Structure

(71) Applicant: Silicon Storage Technology, Inc., San Jose, CA (US)

(72) Inventors: Feng Zhou, Fremont, CA (US); Yi SONG, San Jose, CA (US); HIEU VAN TRAN, San Jose, CA (US); YURI TKACHEV, Sunnyvale, CA (US); XIAN LIU, Sunnyvale, CA (US)

(21) Appl. No.: 19/217,893

(22) Filed: May 23, 2025

Related U.S. Application Data
(60) Provisional application No. 63/757,430, filed on Feb. 12, 2025.

(51) Int. Cl. H10N 70/00; G11C 13/00; H10B 63/00

(52) U.S. Cl. CPC H10N 70/8833; G11C 13/0026; G11C 13/0028; H10B 63/30; H10N 70/021; H10N 70/841; G11C 13/004; G11C 2213/79

(57) ABSTRACT

A resistive random access memory (RRAM) memory cell structure includes a transistor formed on a semiconductor substrate and includes a source region, a drain region and a gate, a lower electrode disposed over the semiconductor substrate and electrically connected to the drain region, a source line electrically connected to the source region, a word line electrically connected to the gate, first and second blocks of resistive switching dielectric material electrically connected to the lower electrode, a first upper electrode electrically connected to the first block of resistive switching dielectric material, a second upper electrode electrically connected to the second block of resistive switching dielectric material, and first and second bit lines electrically connected to the first and second upper electrodes respectively. The first bit line and the second bit line are electrically isolated from each other except for the first and second blocks of resistive switching dielectric material.

### RELATED APPLICATIONS

This application claims the benefit of U.S. Provisional Application No. 63/757,430, filed Feb. 12, 2025, and which is incorporated herein by reference.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive switching dielectric material layer sandwiched between two conductive electrodes. The resistive switching dielectric material is normally insulating. However, by applying the proper voltage across the resistive switching dielectric material layer, a conduction path (typically referred to as a filament) can be formed through the resistive switching dielectric material layer resulting in a lower resistance across the RRAM cell. Once the filament is formed, it can be “reset” (i.e., broken or ruptured, resulting in a high resistance across the RRAM cell) and set (i.e., re-formed, again resulting in a lower resistance across the RRAM cell), by applying the appropriate voltages across the resistive switching dielectric material layer. The low and high resistance states can be utilized to indicate a digital state of “1” or “0” depending upon the resistance state, and thereby provide a reprogrammable non-volatile memory cell that can be programmed to one of two possible program states to store one bit of information.

FIG. 1 shows a conventional configuration of an RRAM memory cell 1. The memory cell 1 includes a resistive device 2 having a resistive switching dielectric material (RSDM) layer 4 sandwiched between (and in physical and electrical contact with) two conductive material layers that form upper electrode 6 and lower electrode 8. The resistive device 2 is connected in series with a transistor 10, having a source region 12 and drain region 14 formed in a semiconductor substrate 16, and a gate 18. Conductive contacts 20 are formed in insulation material 22 covering the transistor 10. A bit line contact 24 is electrically connected to the upper electrode 6. One of the contacts 20 electrically connects the lower electrode 8 to the drain region 14. The other contact 20 electrically connects the source region 12 to a source line contact 26. The transistor 10 is used to select and operate the resistive device 2.

FIGS. 2A-2D show the switching mechanism of the RSDM layer 4. Specifically, FIG. 2A shows the RSDM layer 4 in its initial state after fabrication, where the RSDM layer 4 exhibits a relatively high resistance. FIG. 2B shows the formation of a conductive filament 4a through the RSDM layer 4 by applying the appropriate voltage across the RSDM layer 4. The filament 4a is a conductive path through the RSDM layer 4, such that the RSDM layer 4 exhibits a relatively low resistance across it between the upper and lower electrodes 6, 8 (because of the relatively high conductivity of the filament 4a). FIG. 2C shows the formation of a rupture 4b in filament 4a caused by the application of a “reset” voltage across the RSDM layer 4. The area of the rupture 4b has a relatively high resistance, so that RSDM layer 4 exhibits a relatively high resistance across it. FIG. 2D shows the restoration of the filament 4a in the area of the rupture 4b caused by the application of a “set” voltage across RSDM layer 4. The restored filament 4a means the RSDM layer 4 exhibits a relatively low resistance across it. The relatively low resistance of RSDM layer 4 in the “formed” or “set” states of FIGS. 2B and 2D respectively can represent a digital state (e.g. a “1”), and the relatively high resistance of RSDM layer 4 in the “reset” state of FIG. 2C can represent a different digital state (e.g. a “0”). The reset voltage (which breaks the filament 4a) can have a polarity opposite that of the filament formation and the set voltages, but it can also have the same polarity. The RRAM cell 1 can repeatedly be “reset” and “set,” so it forms a reprogrammable nonvolatile memory cell for storing one bit of information (“0” or “1) represented by two possible program states.

There is a need to scale down the size of the RRAM memory cell.

### BRIEF SUMMARY OF THE INVENTION

The aforementioned problems and needs are addressed by a resistive random access memory (RRAM) memory cell structure comprising a semiconductor substrate, a transistor formed on the semiconductor substrate that includes a source region, a drain region and a gate, a lower electrode disposed over the semiconductor substrate and electrically connected to the drain region, a source line electrically connected to the source region, a word line electrically connected to the gate, a first block of resistive switching dielectric material electrically connected to the lower electrode, a second block of resistive switching dielectric material electrically connected to the lower electrode, a first upper electrode electrically connected to the first block of resistive switching dielectric material, a second upper electrode electrically connected to the second block of resistive switching dielectric material, a first bit line electrically connected to the first upper electrode, and a second bit line electrically connected to the second upper electrode, wherein the first bit line and the second bit line are electrically isolated from each other except for the first and second blocks of resistive switching dielectric material.

A method of forming a resistive random access memory (RRAM) memory cell structure comprises forming a transistor on a semiconductor substrate that includes a source region, a drain region and a gate, forming a lower electrode disposed over the semiconductor substrate and electrically connected to the drain region, forming a source line electrically connected to the source region, forming a word line electrically connected to the gate, forming a first block of resistive switching dielectric material electrically connected to the lower electrode, forming a second block of resistive switching dielectric material electrically connected to the lower electrode, forming a first upper electrode electrically connected to the first block of resistive switching dielectric material, forming a second upper electrode electrically connected to the second block of resistive switching dielectric material, forming a first bit line electrically connected to the first upper electrode, and forming a second bit line electrically connected to the second upper electrode, wherein the first bit line and the second bit line are electrically isolated from each other except for the first and second blocks of resistive switching dielectric material.

Other objects and features of the present disclosure will become apparent by a review of the specification, claims and appended figures.

### BRIEF DESCRIPTION OF THE DRAWINGS

FIG. 1 is a side cross sectional view of a conventional RRAM memory cell.

FIG. 2A is a side cross sectional view of a conventional RRAM memory cell resistive switching dielectric material layer in its initial state.

FIG. 2B is a side cross sectional view of a conventional RRAM memory cell resistive switching dielectric material layer illustrating the formation of a conductive filament.

FIG. 2C is a side cross sectional view of a conventional RRAM memory cell resistive switching dielectric material layer illustrating the formation of a rupture in the conductive filament.

FIG. 2D is a side cross sectional view of a conventional RRAM memory cell resistive switching dielectric material layer illustrating the restoration of the conductive filament in the area of the rupture.

FIG. 3 is a side cross section view of a RRAM memory cell structure.

FIG. 4 is a schematic diagram of the RRAM memory cell structure of FIG. 3.

FIG. 5 is a schematic diagram of an array of the RRAM memory cell structures of FIG. 3.

FIGS. 6-7 are tables showing examples of operational voltages for the array of the RRAM memory cell structures of FIG. 5.

FIG. 8 is a side cross section view of another example of the RRAM memory cell structure.

FIG. 9 is a schematic diagram of the RRAM memory cell structure of FIG. 8.

FIG. 10 is a side cross section view of another example of the RRAM memory cell structure.

FIG. 11 is a schematic diagram of the RRAM memory cell structure of FIG. 10.

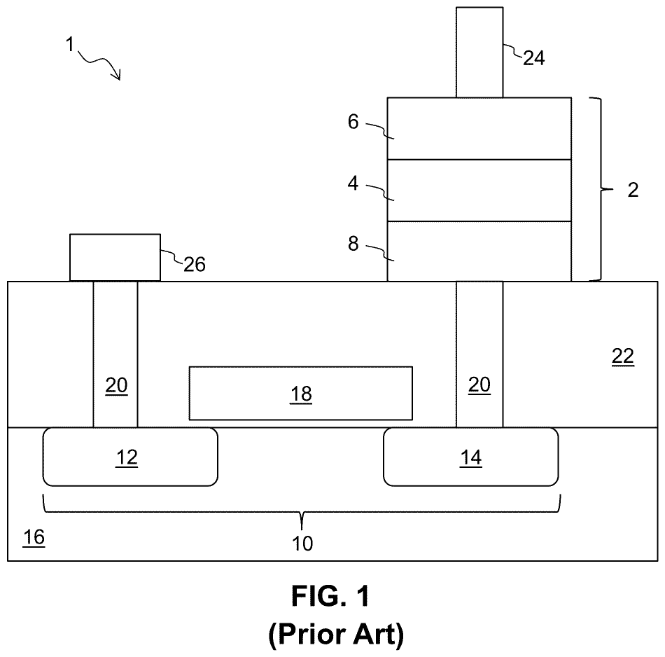

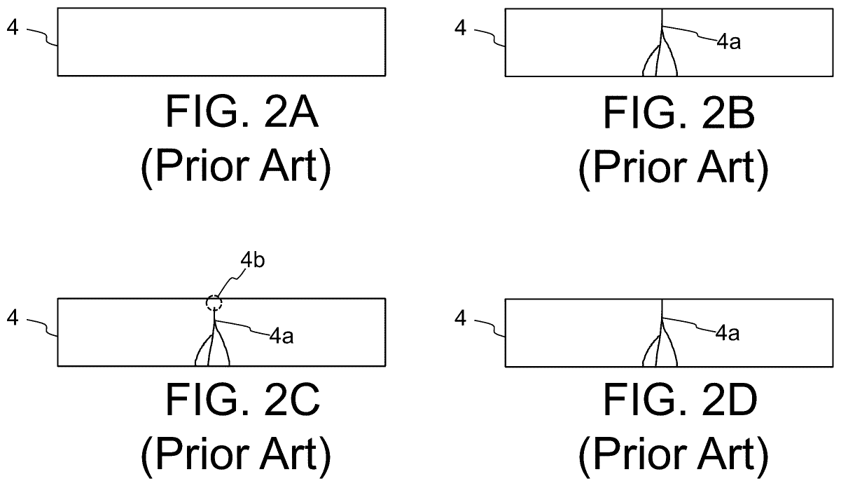

### DETAILED DESCRIPTION OF THE INVENTION

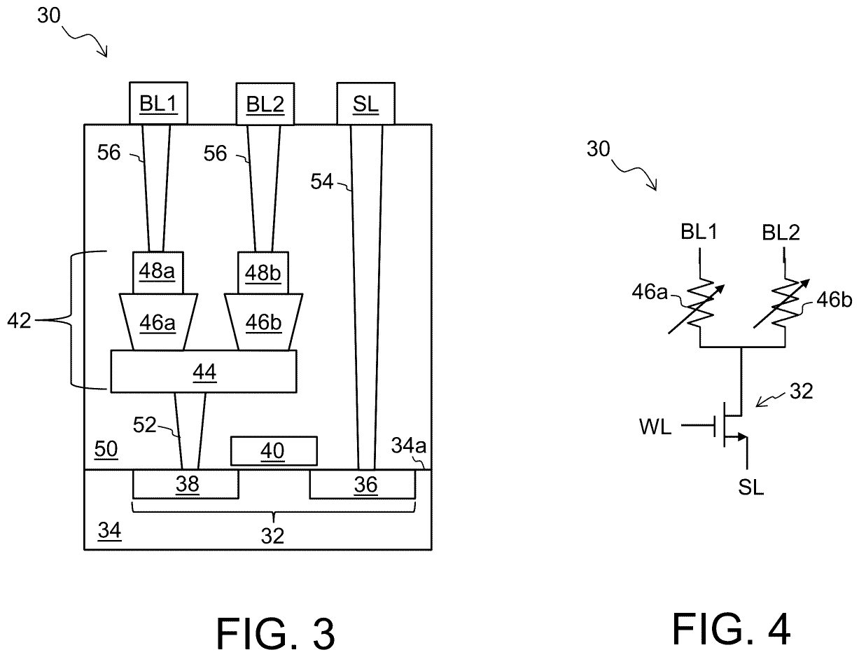

A resistive random access memory (RRAM) memory cell structure 30 is disclosed, and is shown in FIG. 3. The RRAM memory cell structure 30 includes a transistor 32 formed on an upper surface 34a of a semiconductor substrate 34. The transistor 32 includes a source region 36 and drain region 38 formed in the semiconductor substrate 34, and a gate 40 formed over the semiconductor substrate 34. A plurality of resistive devices 42 includes a (common) lower electrode 44 disposed over the semiconductor substrate 34, a first block of resistive switching dielectric material 46a (also referred to herein as first RSDM block 46a) electrically connected to the lower electrode 44, a second block of resistive switching dielectric material 46b (also referred to herein as second RSDM block 46b) electrically connected to the lower electrode 44, a first upper electrode 48a electrically connected to the first RSDM block 46a, and a second upper electrode 48b electrically connected to the second RSDM block 46b. The electrical connection between the lower electrode 44 and the first and second RSDM blocks 46a, 46b can be made by physical contact between the lower electrode 44 and first and second RSDM blocks 46a, 46b.

Each of the first and second RSDM blocks 46a, 46b can be a single layer of resistive switching oxide such as a transition metal oxide (e.g., HfO₂, Al₂O₃, TaOₓ, TiOₓ, WOₓ, VOₓ, CuOₓ). Each of the first and second RSDM blocks 46a, 46b can also include multiple sublayers of different oxides and metals. Non-limiting examples of sublayers that can be included in the first and second RSDM blocks 46a, 46b can include a sublayer of oxygen scavenger metal such as Ti or Ta on a sublayer of a transition metal oxide (e.g., HfO₂, Al₂O₃, TaOₓ, TiOₓ, WOₓ, VOₓ, CuOₓ), or a sublayer of HfO₂ and a sublayer of Al₂O₃, or a sublayer of HfO₂ and a sublayer of Hf and a sublayer of TaOₓ, or a sublayer of HfO₂ and a sublayer of Ti and a sublayer of TiOₓ. One or more conductive filaments can be formed in the first and second RSDM blocks 46a, 46b (i.e., using the forming and set operations discussed herein), where the first and second RSDM blocks 46a, 46b are considered to be in their low resistance state (also referred to herein as the “L state”). One or more ruptures to those filaments can be formed in the first and second RSDM blocks 46a, 46b (i.e., using the reset operation discussed herein), where the first and second RSDM blocks 46a, 46b are considered to be in their high resistance state (also referred to herein as the “H state”).

The RRAM memory cell structure 30 may be surrounded by insulation material 50. The lower electrode 44 is electrically connected to the drain region 38 by an electrical contact 52 (e.g., a conductive material in a via hole in the insulation material 50). Source region 36 is electrically connected to a source line SL by an electrical contact 54. The first and second upper electrodes 48a, 48b are electrically connected to first and second bit lines BL1, BL2 respectively by electrical contacts 56.

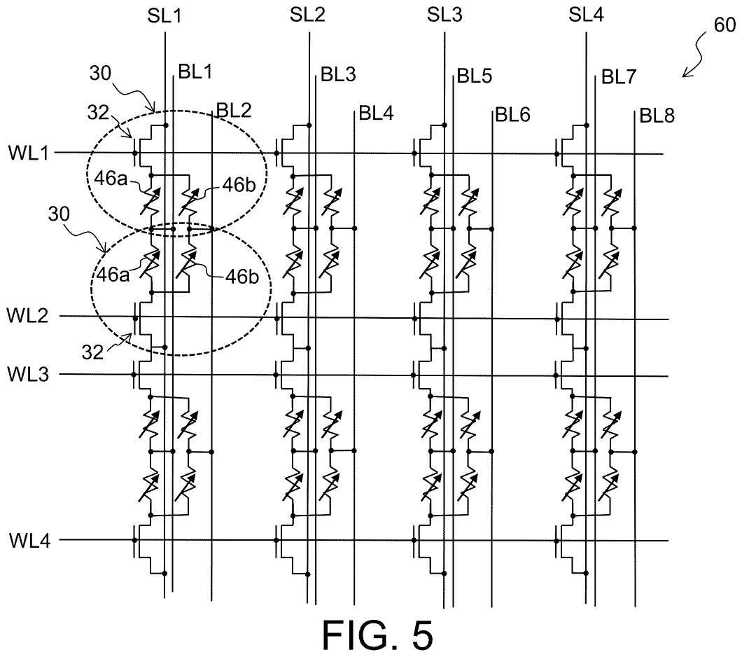

FIG. 4 is a schematic diagram of the electrical connections of RRAM memory cell structure 30. First bit line BL1 is electrically connected to the first upper electrode 48a (e.g., by way of respective electrical contact 56), and second bit line BL2 is electrically connected to the second upper electrode 48b (e.g., by way of respective electrical contact 56). A word line WL is electrically connected to the gate 40 of transistor 32. Source line SL is electrically connected to source region 36 of transistor 32 by way of electrical contact 54. A plurality of RRAM memory cell structures 30 can be formed in an array 60 on a single semiconductor substrate 34, as illustrated schematically in FIG. 5. In array 60, the RRAM memory cells structures 30 are arranged in rows and columns, with each of the columns including two of the bit lines BL and one of the source lines SL connected thereto, and with each of the rows including one word line WL connected thereto.

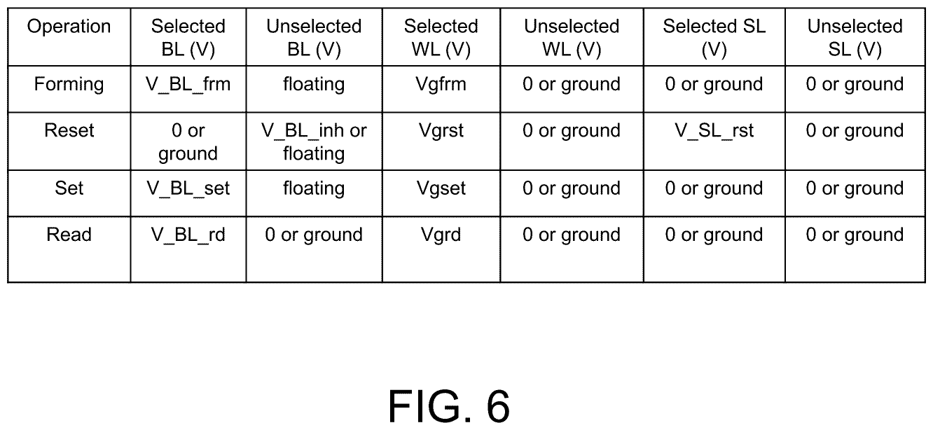

The voltages for the forming, set, reset and read operations on one of the RSDM blocks 46a, 46b (i.e., the selected RSDM block, along with the selected bit line BL, selected word WL and selected source line SL associated with that selected RSDM block), with any other RSDM blocks and their associated lines in the array being unselected, are summarized in FIG. 6. Taking RSDM block 46a in FIG. 3 as an example of the selected RSDM block, the forming operation to initially place the RSDM block 46a to its low resistive state can include placing a filament forming voltage V_BL_frm on the first bit line BL1 (and therefore on upper electrode 48a), and a positive voltage Vgfrm on the selected word line WL (to turn on transistor 32 so as to electrically connect lower electrode 44 to the source line SL through transistor 32). A zero or ground voltage can be placed on the selected and unselected source lines SL and unselected word lines WL. The unselected bit lines BL can be floating. The voltage potential V_BL_frm across RSDM block 46a will cause sufficient current to create one or more conductive filaments therein, placing the RSDM block 46a in its L state. This combination of voltages can result in the forming operation only affecting the selected RSDM block 46a, without affecting the unselected RSDM blocks in array 60.

The reset operation to place the RSDM block 46a back to its H state can include placing a filament resetting voltage V_SL_rst on the selected source line SL, and a positive voltage Vgrst on the selected word line WL (to turn on transistor 32 so as to electrically connect lower electrode 44 to source line SL through transistor 32). A zero or ground voltage can be placed on the unselected source lines SL, the unselected word lines WL and the selected bit line BL. The unselected bit lines BL can be floating, or an inhibit voltage V_BL_inh can be placed on the unselected bit lines BL. The voltage potential V_SL_rst will cause current to flow in the opposite direction as in the forming operation, which will reset the one or more filaments, placing the RSDM block 46a back in its H state. This combination of voltages can result in the reset operation only affecting the selected RSDM block 46a, without affecting the unselected RSDM blocks in array 60.

The set operation to change the RSDM block 46a from its H state to its L state can include placing a filament forming voltage V_BL_set on the first bit line BL1 (and therefore on upper electrode 48a), and a positive voltage Vgset on the selected word line WL (to turn on transistor 32 so as to electrically connect lower electrode 44 to source line SL through transistor 32). A zero or ground voltage can be placed on the selected and unselected source lines SL and the unselected word lines WL. The unselected bit lines BL can be floating. The voltage potential V_BL_set across RSDM block 46a will create one or more filaments, placing the RSDM block 46a in its L state. This combination of voltages can result in the set operation only affecting the selected RSDM block 46a, without affecting the unselected RSDM blocks in array 60.

The read operation to determine the program state of RSDM block 46a can include placing a read voltage V_BL_rd on the selected bit line BL, and a positive voltage Vgrd on the selected word line WL (to turn on transistor 32 so as to electrically connect lower electrode 44 to source line SL through transistor 32). A zero or ground voltage can be placed on the selected and unselected source lines SL, the unselected word lines WL and the unselected bit lines BL. The current flowing from the selected bit line BL, through RSDM block 46a, and to the selected source line SL is then measured, and will have a different value depending whether the RSDM block 46a is in its H state (relatively low or no current) or its L state (relatively high current). This combination of voltages can result in the read operation only affecting the selected RSDM block 46a, without affecting the unselected RSDM blocks in array 60.

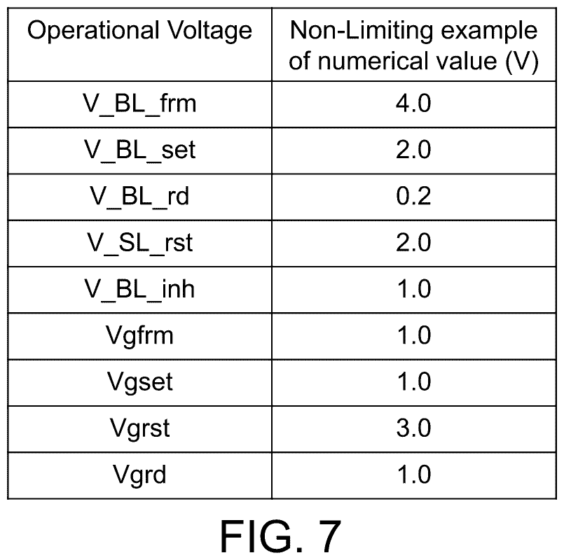

FIG. 7 provides non-limiting numerical examples of the voltage values for the forming, set, reset and read operations of FIG. 6. Depending on the combination of existing and desired resistance states, the forming, set or reset operations could be implemented concurrently on more than one of the RSDM blocks 46 in the array 60.

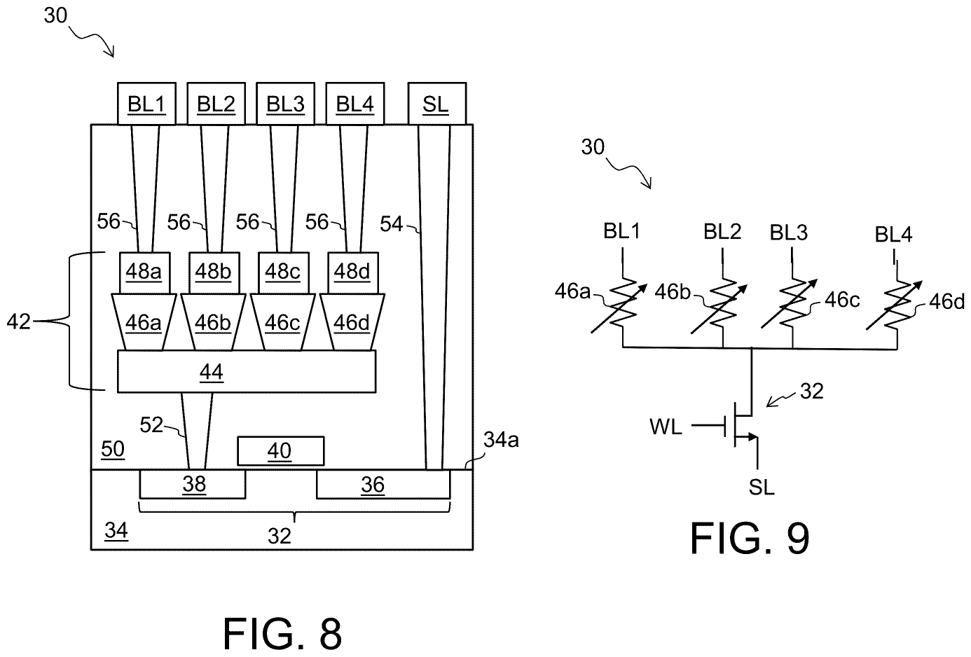

While the RRAM memory cell structure 30 in the example of FIGS. 3-5 includes two RSDM blocks 46a and 46b, more than two RSDM blocks 46 can be included in each RRAM memory cell structure 30. For example, as illustrated in FIGS. 8-9, four RSDM blocks 46a-46d (along with associated upper electrodes 48a-48d and respective electrical contacts 56, and associated bit lines BL1-BL4) can be included in RRAM memory cell structure 30.

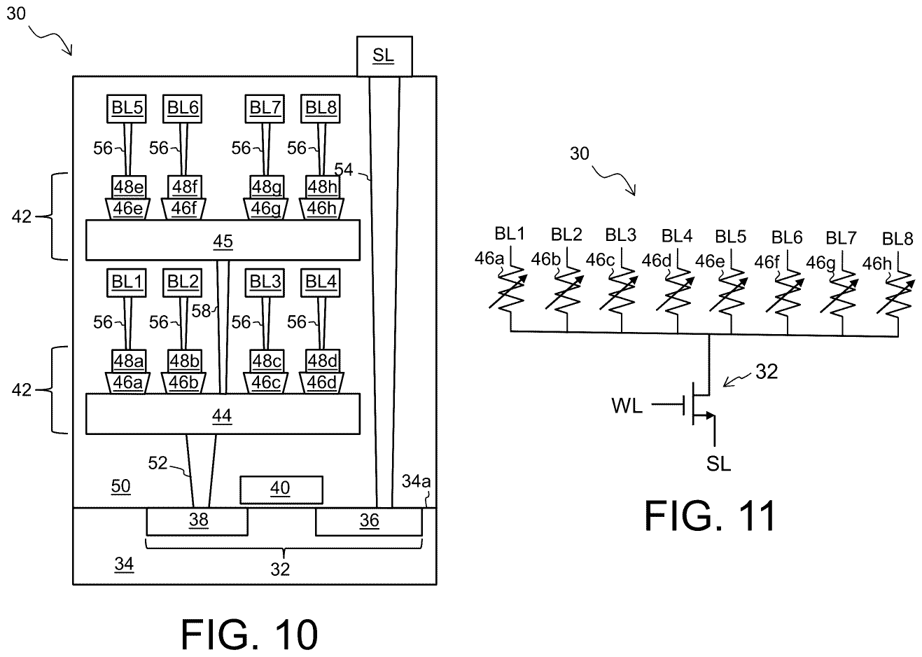

FIGS. 10-11 illustrates another example, where RRAM memory cell structure 30 includes eight RSDM blocks 46a-46h and respective upper electrodes 48a-48h, respective electrical contacts 56, and bit lines BL1-BL8. To save space, a second lower electrode 45 can be formed vertically over (relative to semiconductor substrate 34) lower electrode 44 and RSDM blocks 46a-46d and electrically connected to the lower electrode 44 by electrical contact 58, with RSDM blocks 46e-46h vertically over (relative to semiconductor substrate 34) the second lower electrode 45 and electrically connected to the second lower electrode 45. The electrical connection between the second lower electrode 45 and the RSDM blocks 46e-46h can be made by physical contact there between. For the example of FIGS. 10-11, while four RSDM blocks 46a-46d are included between lower electrode 44 and second lower electrode 45 and electrically connected to lower electrode 44, any number (i.e., one or more) of RSDM blocks 46 can be included between lower electrode 44 and second lower electrode 45 and electrically connected to the lower electrode 44. Similarly, while four RSDM blocks 46e-46h are included vertically over and electrically connected to second lower electrode 45, any number (i.e., one or more) of RSDM blocks 46 can be included vertically over and electrically connected to second lower electrode 45.

There are many advantages of the RRAM memory cell structure 30 described herein. The formation of some or all of the components of resistive devices 42 vertically over the transistor 32 is an effective use of space, where multiple RSDM blocks 46a-46n can be formed in the space vertically over transistor 32 (i.e., RSDM blocks 46a-46n are disposed vertically over at least a portion of transistor 32) to store multiple bits of information, which allows for more storage capacity in an array of RRAM memory cell structures 30 per unit area of the semiconductor substrate 34. The bit lines BL are electrically isolated from each except for the RSDM blocks 46 (i.e., any current path between the bit lines BL would be through the RSDM blocks 46). This configuration allows for independent control of each bit line BL and the respective RSDM block 46 electrically connected thereto, and the independent operation on each RSDM block 46 with reduced program state disturbance to other RSDM blocks 46.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are exemplary only, and should not be deemed to limit the claims. Further, as is apparent from the claims and specification, not all method operations need be performed in the exact order illustrated or claimed, but rather in any order (unless there is an explicitly recited limitation on any order) that allows the proper formation of the RRAM memory cell structures 30 described herein. Single layers of material could be formed as multiple layers of such or similar materials, and vice versa. The terms “forming” and “formed” as used herein shall include material deposition, material growth, or any other technique in providing the material as disclosed or claimed. The claims are comprising claims unless otherwise stated, and therefore “each” of a plurality of elements having a limitation does not preclude the inclusion of additional such elements lacking the limitation unless otherwise specifically claimed. It should be noted that reference herein to circuitry, or a module of circuitry, or the like, to perform or configured to perform an operation refers to the physical structure of the circuit (i.e., the capabilities of the circuitry as dictated by its structure), and does not refer to any method or actual use of the circuitry.

What is claimed is:

1. A resistive random access memory (RRAM) memory cell structure comprising:
a semiconductor substrate;
a transistor formed on the semiconductor substrate that includes a source region, a drain region and a gate;
a lower electrode disposed over the semiconductor substrate and electrically connected to the drain region;
a source line electrically connected to the source region;
a word line electrically connected to the gate;
a first block of resistive switching dielectric material electrically connected to the lower electrode;
a second block of resistive switching dielectric material electrically connected to the lower electrode;
a first upper electrode electrically connected to the first block of resistive switching dielectric material;
a second upper electrode electrically connected to the second block of resistive switching dielectric material;
a first bit line electrically connected to the first upper electrode; and
a second bit line electrically connected to the second upper electrode;
wherein the first bit line and the second bit line are electrically isolated from each other except for the first and second blocks of resistive switching dielectric material.

2. The resistive random access memory (RRAM) memory cell structure of claim 1, wherein the first block of resistive switching dielectric material and the second block of resistive switching dielectric material comprise one of HfO2, Al2O3, TaOx, TiOx, WOx, VOx or CuOx.

3. The resistive random access memory (RRAM) memory cell structure of claim 1, wherein the first block of resistive switching dielectric material and the second block of resistive switching dielectric material comprise a sublayer of HfO₂ and a sublayer of Al₂O₃.

4. The resistive random access memory (RRAM) memory cell structure of claim 1, wherein the first block of resistive switching dielectric material and the second block of resistive switching dielectric material comprise a sublayer of HfO₂, a sublayer of Hf, and a sublayer of TaOx.

5. The resistive random access memory (RRAM) memory cell structure of claim 1, wherein the first block of resistive switching dielectric material and the second block of resistive switching dielectric material comprise a sublayer of HfO₂, a sublayer of Ti, and a sublayer of TiOx.

6. The resistive random access memory (RRAM) memory cell structure of claim 1, wherein the first block of resistive switching dielectric material and the second block of resistive switching dielectric material are disposed vertically over at least a portion of the transistor.

7. The resistive random access memory (RRAM) memory cell structure of claim 1, comprising:
a third block of resistive switching dielectric material electrically connected to the lower electrode;
a third upper electrode electrically connected to the third block of resistive switching dielectric material; and
a third bit line electrically connected to the third upper electrode;
wherein the first bit line, the second bit line and the third bit line are electrically isolated from each other except for the first, second and third blocks of resistive switching dielectric material.

8. The resistive random access memory (RRAM) memory cell structure of claim 1, comprising:
a third block of resistive switching dielectric material electrically connected to the lower electrode;
a fourth block of resistive switching dielectric material electrically connected to the lower electrode;
a third upper electrode electrically connected to the third block of resistive switching dielectric material;
a fourth upper electrode electrically connected to the fourth block of resistive switching dielectric material;
a third bit line electrically connected to the third upper electrode; and
a fourth bit line electrically connected to the fourth upper electrode;
wherein the first bit line, the second bit line, the third bit line and the fourth bit line are electrically isolated from each other except for the first, second, third and fourth blocks of resistive switching dielectric material.

9. The resistive random access memory (RRAM) memory cell structure of claim 1, comprising:
a second lower electrode disposed vertically over and electrically connected to the lower electrode;
wherein the first block of resistive switching dielectric material is in physical contact with the lower electrode and is disposed between the lower electrode and the second lower electrode;
wherein the second block of resistive switching dielectric material is disposed vertically over and in physical contact with the second lower electrode.

10. The resistive random access memory (RRAM) memory cell structure of claim 9, comprising:
a third block of resistive switching dielectric material disposed vertically over and in physical contact with the lower electrode;
a fourth block of resistive switching dielectric material disposed vertically over and in physical contact with the second lower electrode;
a third upper electrode electrically connected to the third block of resistive switching dielectric material;
a fourth upper electrode electrically connected to the fourth block of resistive switching dielectric material;
a third bit line electrically connected to the third upper electrode; and
a fourth bit line electrically connected to the fourth upper electrode;
wherein the first bit line, the second bit line, the third bit line and the fourth bit line are electrically isolated from each other except for the first, second, third and fourth blocks of resistive switching dielectric material.

11. A method of forming a resistive random access memory (RRAM) memory cell structure, comprising:
forming a transistor on a semiconductor substrate that includes a source region, a drain region and a gate;
forming a lower electrode disposed over the semiconductor substrate and electrically connected to the drain region;
forming a source line electrically connected to the source region;
forming a word line electrically connected to the gate;
forming a first block of resistive switching dielectric material electrically connected to the lower electrode;
forming a second block of resistive switching dielectric material electrically connected to the lower electrode;
forming a first upper electrode electrically connected to the first block of resistive switching dielectric material;
forming a second upper electrode electrically connected to the second block of resistive switching dielectric material;
forming a first bit line electrically connected to the first upper electrode; and
forming a second bit line electrically connected to the second upper electrode;
wherein the first bit line and the second bit line are electrically isolated from each other except for the first and second blocks of resistive switching dielectric material.

12. The method of claim 11, wherein the first block of resistive switching dielectric material and the second block of resistive switching dielectric material comprise one of HfO2, Al2O3, TaOx, TiOx, WOx, VOx or CuOx.

13. The method of claim 11, wherein the first block of resistive switching dielectric material and the second block of resistive switching dielectric material comprise a sublayer of HfO₂ and a sublayer of Al₂O₃.

14. The method of claim 11, wherein the first block of resistive switching dielectric material and the second block of resistive switching dielectric material comprise a sublayer of HfO₂, a sublayer of Hf, and a sublayer of TaOx.

15. The method of claim 11, wherein the first block of resistive switching dielectric material and the second block of resistive switching dielectric material comprise a sublayer of HfO₂, a sublayer of Ti, and a sublayer of TiOx.

16. The method of claim 11, wherein the first block of resistive switching dielectric material and the second block of resistive switching dielectric material are disposed vertically over at least a portion of the transistor.

17. The method of claim 11, comprising:
forming a third block of resistive switching dielectric material electrically connected to the lower electrode;
forming a third upper electrode electrically connected to the third block of resistive switching dielectric material; and
forming a third bit line electrically connected to the third upper electrode;
wherein the first bit line, the second bit line and the third bit line are electrically isolated from each other except for the first, second and third blocks of resistive switching dielectric material.

18. The method of claim 11, comprising:
forming a third block of resistive switching dielectric material electrically connected to the lower electrode;
forming a fourth block of resistive switching dielectric material electrically connected to the lower electrode;
forming a third upper electrode electrically connected to the third block of resistive switching dielectric material;
forming a fourth upper electrode electrically connected to the fourth block of resistive switching dielectric material;
forming a third bit line electrically connected to the third upper electrode; and
forming a fourth bit line electrically connected to the fourth upper electrode;
wherein the first bit line, the second bit line, the third bit line and the fourth bit line are electrically isolated from each other except for the first, second, third and fourth blocks of resistive switching dielectric material.

19. The method of claim 11, comprising:
forming a second lower electrode disposed vertically over and electrically connected to the lower electrode;
wherein the first block of resistive switching dielectric material is in physical contact with the lower electrode and is disposed between the lower electrode and the second lower electrode;
wherein the second block of resistive switching dielectric material is disposed vertically over and in physical contact with the second lower electrode.

20. The method of claim 19, comprising:
forming a third block of resistive switching dielectric material disposed vertically over and in physical contact with the lower electrode;
forming a fourth block of resistive switching dielectric material disposed vertically over and in physical contact with the second lower electrode;
forming a third upper electrode electrically connected to the third block of resistive switching dielectric material;
forming a fourth upper electrode electrically connected to the fourth block of resistive switching dielectric material;
forming a third bit line electrically connected to the third upper electrode; and
forming a fourth bit line electrically connected to the fourth upper electrode;
wherein the first bit line, the second bit line, the third bit line and the fourth bit line are electrically isolated from each other except for the first, second, third and fourth blocks of resistive switching dielectric material.
